(19) United States
(12) Patent Application Publication
(10) Pub. No.: US 2026/0121647 A1
(43) Pub. Date: Apr. 30, 2026

(54) DIGITAL-TO-ANALOG CONVERTER SYSTEM

(71) Applicant: Infineon Technologies AG, Neubiberg (DE)

(72) Inventors: Francesco Conzatti, Villach (AT); Matteo Dalla Longa, Villach (AT); Alan Paussa, Villach (AT)

(21) Appl. No.: 19/366,077

(22) Filed: Oct. 22, 2025

(30) Foreign Application Priority Data
Oct. 24, 2024 (DE) 102024210280.6

(51) Int. Cl. H03M 1/06

(52) U.S. Cl. CPC H03M 1/0604

(57) ABSTRACT

In accordance with an embodiment, a digital-to-analog converter (DAC) system includes: a main current-steering DAC having an input coupled to a digital system input having n input lines; an active buffer having an input coupled to an output of the main current-steering DAC, and an output of conﬁgured to output a first current to an analog system output; and an auxiliary current-steering DAC, having an input coupled to the digital system input, and an output conﬁgured to output a second current to the analog system output, where the input of the auxiliary current-steering DAC is connected only to a real subset of the n input lines of the digital system input, the real subset of input lines having k input lines.

This application claims the benefit of German Patent Application No. 102024210280.6, filed on October 24, 2024, which application is hereby incorporated herein by reference.

### TECHNICAL FIELD

Embodiments of the invention generally relate to electronic systems, and more specifically relate to a digital-to-analog converter (DAC) system.

### BACKGROUND

At least for some digital-to-analog converters, DACs, high linearity is desired and may be considered as an important quality feature of a DAC. Since the linearity of a DAC may depend on several factors, this may be a challenge for many types of DACs. Particularly, any measure that can contribute to provide high linearity for DACs that operate with high frequencies may be desirable.

### SUMMARY

An example of the present disclosure relates to a digital-to-analog converter, DAC, system for converting a digital input signal from a digital system input to an analog output signal at an analog system output. The digital system input has n input lines. The DAC system comprises a main current-steering DAC, whose input is connected to the digital system input, and it comprises an active buffer, whose input is connected to an output of the main current-steering DAC, an output of the active buffer being conﬁgured for outputting a first current to the analog system output. The DAC system further comprises an auxiliary current-steering DAC, whose input is connected to the digital system input, an output of the auxiliary current-steering DAC being conﬁgured for outputting a second current to the analog system output. The input of the auxiliary current-steering DAC is connected only to a real subset of input lines of the digital system input, the real subset of input lines having k input lines.

### BRIEF DESCRIPTION OF THE DRAWINGS

The drawings depict:

FIG. 1 schematically a baseband transmit circuit according to an embodiment;

FIG. 2 schematically a digital-to-analog converter, DAC, system according to an embodiment;

FIG. 3 schematically a DAC system according to another embodiment;

FIG. 4 schematically a DAC system according to a further embodiment;

FIG. 5 schematically a detail of a DAC system according to an embodiment; and

FIG. 6 schematically an example diagram showing an effect of the DAC system.

### DETAILED DESCRIPTION OF ILLUSTRATIVE EMBODIMENTS

A digital-to-analog converter, DAC, generally converts a digital input signal, which comprises a number of n input lines, to an analog output signal. A DAC system may have the same task, but it may comprise more than one DAC. The number of input lines may indicate a resolution of the DAC. The analog output signal may be a current or may be a voltage, for example when a high output impedance is desired. The voltage range of the DAC may depend on its specified purpose and/or on the system, within which the DAC is used. An example of an output voltage range may stretch from 0 V to 5 V or, for a differential output, from –5 V to +5 V.

Some embodiments are directed to digital-to-analog converters (DAC), which may include, for example, a DAC system and/or wide-bandwidth DACs. Embodiments may further relate to a baseband transmit circuit, a system-on-chip (SoC), and to a use of such a circuit or system.

The DAC system comprises a main current-steering DAC, whose input is connected to the digital system input. The digital system input may be connected to a processor, e.g. to a DSP (Digital Signal Processor). The main current-steering DAC is connected to all of the input lines. The main current-steering DAC may have means to provide basically a high linearity, e.g. it may comprise resistors and/or semiconductors of high precision. The main DAC’s output is connected to an input of an active buffer, which is conﬁgured for outputting a first current to the analog system output. The active buffer may comprise an operational amplifier (“op-amp”), whose input – and, thus, the input of the active buffer – may act as a so-called “virtual ground”, into which the main current-steering DAC discharges. The virtual ground is a concept that a selected node within a circuit – for instance an input of an active buffer, and/or an inverting input of an op-amp – is not connected to a real ground, but is considered as having a constant voltage with respect to the real ground. Unfortunately, this may not be the case in real circuits. For instance, when operating at high frequencies, the op-amp may not be fast enough for providing a feedback that compensates voltage fluctuations at the virtual ground completely. In case of a DAC, these voltage fluctuations at the virtual ground may deteriorate the linearity of the DAC. This effect may be relevant for DACs that operate at high sampling frequencies and/or with a high resolution.

The DAC system further comprises an auxiliary current-steering DAC. The auxiliary DAC’s input is connected to the digital system input. The auxiliary DAC’s output is conﬁgured for outputting a second current to the analog system output. The auxiliary DAC’s output is the same node as the output of the active buffer. The current of the auxiliary current-steering DAC’s output may have an opposite direction than the current direction of the active buffer. This second current from the auxiliary DAC’s output may contribute to compensate the fluctuations at the output of the active buffer, which are caused by the fluctuations of or at the virtual ground. The input of the auxiliary current-steering DAC is connected only to a real subset of input lines of the digital system input, the real subset of input lines having k (of n) input lines. For improving the linearity of the DAC system, it may not be necessary to compensate said fluctuations completely, but a partial compensation may result in an improvement of the DAC system’s linearity. For example, the DAC system described here can also be used as DAC for high frequencies. Furthermore, this may contribute to a relaxation of the gain and/or bandwidth requirements of the operational amplifier. This in turn may help to reduce the power consumption.

In various embodiments, the real subset of the input lines is an MSB-portion of the input lines of the digital system input, the MSB-portion consisting of k most significant bits, MSBs. Using the MSB-portion as embodiment of the “real subset” of the digital system input, may compensate said fluctuations efficiently.

In various embodiments, the real subset of the input lines consists of less than or equal to half of the input lines of the digital system input. This may, on the one hand, provide a sufficient compensation of the fluctuations of interest, but may also, on the other hand, allow a quite cost-saving implementation (e.g. in relation to a consumption of die-size) of the auxiliary current-steering DAC.

In some embodiments, the digital system input has between n=2 and n=16 input lines, and the real subset of the input lines has between k=1 and k=7 lines. For instance, for an n=2 one may select a k=1, for n=16 a k=7, for n=12 a k=6 or k=5, and so on.

In some embodiments, the digital system input has between n=5 and n=14 input lines, and the real subset of the input lines has between k=2 and k=6 lines. For instance, for an n=5 one may select a k=2, for n=14 a k=6, for n=10 a k=5, and so on.

In various embodiments, a voltage at the input of the active buffer is compensated by means of the second current from the auxiliary current-steering DAC. The second current from the auxiliary current-steering DAC may be similar (or, in some cases, equal) to the current from the active buffer, but may have an opposite direction. This may reduce the current provided by the active buffer and therefore (as an effect) the fluctuation of the virtual ground, thus improving the linearity of the DAC system.

In various embodiments, the DAC system further comprises a notch filter, arranged before the analog system output of the DAC system. The notch filter may have a central frequency equal to a sampling frequency of the DAC system. This may reduce or remove the images produced by the DACs around their sampling clock.

In various embodiments, the active buffer is an active low-pass filter. This may reduce a (very high frequency) noise at the output of the main DAC, thus reducing effects of such an unwanted noise on the DAC system.

In various embodiments, the second current is between 90 % and 99 % of the first current. An example of the second current may be 97 % of the first current.

In various embodiments, the input lines of the main current-steering DAC uses a unary converter principle. An example of the unary converter principle may be to use a so-called thermometric converter principle for the main DAC. This converter principle provides a very good linearity and can be used also for high-frequency DACs.

In various embodiments, the input lines of the auxiliary current-steering DAC uses a binary converter principle. This may save die-space for the auxiliary DAC and may also improve the DAC system’s linearity. The effect of saving die-space may even be higher when the input of the auxiliary current-steering DAC is connected only to a real subset of input lines of the digital system input, so that less “partial DACs” are needed in the die-area of the auxiliary DAC, thus making this part of the die smaller.

In various embodiments, the auxiliary current-steering DAC further comprises a low-pass filter. The low-pass filter is arranged before the output of the auxiliary current-steering DAC. The low-pass filter may be a passive first order RC-filter. The low-pass filter may contribute to improve the image rejection at the auxiliary DAC’s output.

In various embodiments, the auxiliary current-steering DAC further comprises an output mirror. The output mirror is arranged before the output of the auxiliary current-steering DAC. So, the output-current of the partial DACs – e.g. one partial DAC per bit – is summed up and forwarded into the output mirror. The output mirror may comprise one or more n-MOS FETs. The output mirror may be realized as a double mirror. The output mirror may increase the DAC output impedance. The output mirror circuit comprises the auxiliary DAC’s low-pass filter, which may be a passive first order RC-filter. This low-pass filter may improve the image rejection.

In various embodiments, the DAC system supports a sampling frequency between 1 MHz and 1 GHz. In an embodiment, the DAC system supports a sampling frequency between 5 MHz and 200 MHz. This applicability to such high frequencies makes the DAC system usable for a broad range of applications. Of course, the DAC system can also be used within systems with lower or higher frequencies.

In various embodiments, the digital system input is designed as differential digital input, and/or the analog system output is designed as differential analog output. Differential inputs and/or outputs may be implemented in systems that demand a high data rate, a high ground noise immunity and/or low electromagnetic interference.

In various embodiments, the input of the main current-steering DAC is connected to all of the input lines of the digital system input, i.e. k=n. This may further improve the linearity of the DAC system.

An aspect relates to a baseband transmit (TX) circuit. The baseband transmit circuit comprises a Digital Signal Processor, DSP, conﬁgured for outputting a digital number, the digital number having an output width of n bits and a DAC system as described above and/or below. An input of the DAC system has an input width of n bits and is connected to an output of the DSP. The baseband transmit circuit further comprises a low-pass filter, that is connected to an output of the DAC system, and a modulator, conﬁgured for mixing an output of the low-pass filter with an output of a local oscillator. An output of the modulator is connected to an amplifier, and is conﬁgured for providing an antenna signal to an antenna, the antenna being conﬁgured for transmitting the antenna signal. The baseband transmit circuit may be connected and/or combined with a corresponding receiving (RX) circuit, thus building a wireless system unit.

An aspect relates to a system-on-chip, SoC, system, which comprises a digital-to-analog converter, DAC, system as described above and/or below.

An aspect relates to a use of a digital-to-analog converter, DAC, system as described above and/or below for a baseband transmit circuit, for a WiFi system, for a Bluetooth-based system, for a wide-bandwidth, high-linearity baseband transmit circuit, for an ultra-wideband system, for a cellular system, for an Ethernet system, and/or for a cable modem system.

It should be noted that two or more embodiments described above and/or below can be combined, as far as technically feasible.

For further elucidation, the disclosure is described by means of embodiments shown in the figures. These embodiments are to be considered as examples only, but not as limiting.

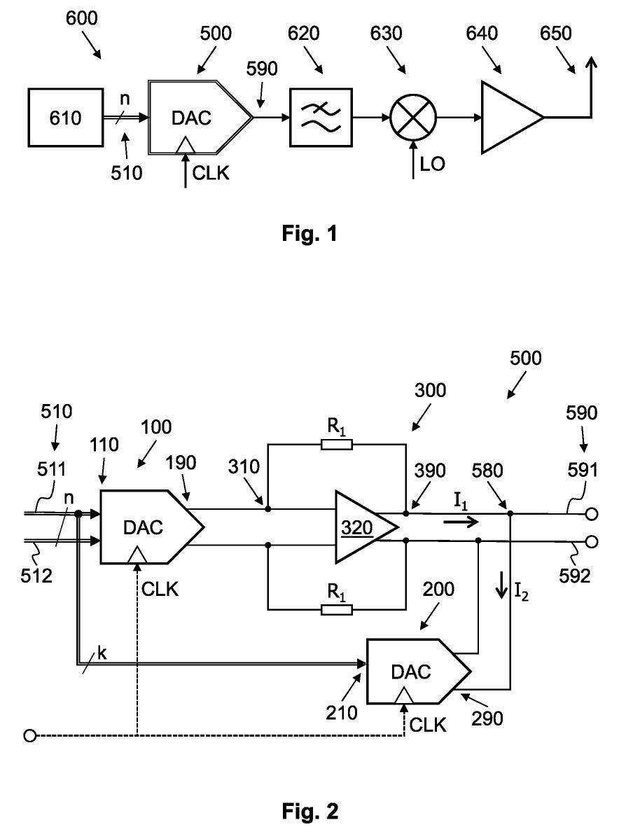

FIG. 1 schematically shows a baseband transmit circuit 600 according to an embodiment. The baseband transmit circuit 600 comprises a processor 610, for example a Digital Signal Processor, DSP, or any other type of processor that is able to or conﬁgured for outputting a digital number. The digital number has an output width of n bits. The baseband transmit circuit 600 further comprises a DAC system 500 as described above and/or below. The DAC system 500 has an input 510, with an input width of n bits. The DAC system 500 is connected to an output of the DSP 610. At an output 590 of the DAC system 500, a low-pass filter 620, is connected. The output of the low-pass filter 620 is connected to a modulator or mixer 630, conﬁgured for mixing the output of the low-pass filter 620 with an output of a local oscillator LO. The output of the modulator 630 provides a high frequency, which is intended for being sent by a suitable antenna. For this, the output of the modulator 630 is connected to an amplifier 640, which is conﬁgured for providing an antenna signal to an antenna 650. The antenna 650 is conﬁgured for transmitting the antenna signal.

FIG. 2 schematically shows a digital-to-analog converter, DAC, system 500 according to an embodiment. The DAC system 500 is suited and/or conﬁgured for converting a digital input signal from a digital system input 510 to an analog output signal at an analog system output 590. The digital system input 510 has n input lines and, thus, a resolution of n bits. The DAC system 500 comprises a main current-steering DAC 100, whose input 110 is connected to the digital system input 510. The main DAC 100 may have a sampling frequency CLK of, for example, between 1 MHz and 1 GHz. An output 190 of the main current-steering DAC 100 is connected to input 310 of an active buffer 300. The active buffer 300 comprises an op-amp 320, and a resistor R₁ in the op-amp’s feedback loops. The input 310 of the active buffer 300 may be the same node as an inverting input of the op-amp 320. The input 310 of the active buffer 300 may act as virtual ground. The active buffer 300 is conﬁgured for outputting, at its output 390, a first current I₁ to an output 580. In some embodiments, the output 580 may be identical to an analog system output 590. The analog system output 590 in the embodiment shown is designed as a differential output, with terminals 591 and 592.

In the embodiment shown, a notch filter 400 is arranged before the analog system output 590 of the DAC system 500, i.e. here: between the output node 580 and the analog system output 590. The notch filter 400 has a central frequency equal to a sampling frequency CLK of the DAC system 500.

The DAC system 500 further comprises an auxiliary current-steering DAC 200, whose input 210 is connected to the digital system input 510. In the embodiment shown, only a real subset of the n input lines of the digital system input 510 is led to the digital system input 510, namely only a part 511 consisting of k (of the n) input lines. The auxiliary DAC 200 has the same sampling frequency CLK as the main DAC 100. The part 512 of the input lines is led to and used by the main current-steering DAC 100, only. An output 290 of the auxiliary DAC 200 is conﬁgured for outputting a second current I₂ to the analog system output 590 (here: 580). Since, in the embodiment of FIG. 2, the input 210 of the auxiliary current-steering DAC 200 is connected only to a real subset of input lines 511 (having k input lines) of the digital system input 510, the first current I₁ may not be compensated completely by the second current I₂, but only partly. For at least some DAC systems, the second current I₂may be in a range between 90 % and 99 % – say: 97 % – of the first current I₁. The second current I₂ may compensate fluctuations from the first current I₁ from the active buffer 300. Said fluctuations may be caused by fluctuations of the virtual ground 310. This may improve the linearity of the DAC system 500, e.g. compared to a linearity of a DAC system that uses only the main current-steering DAC 100.

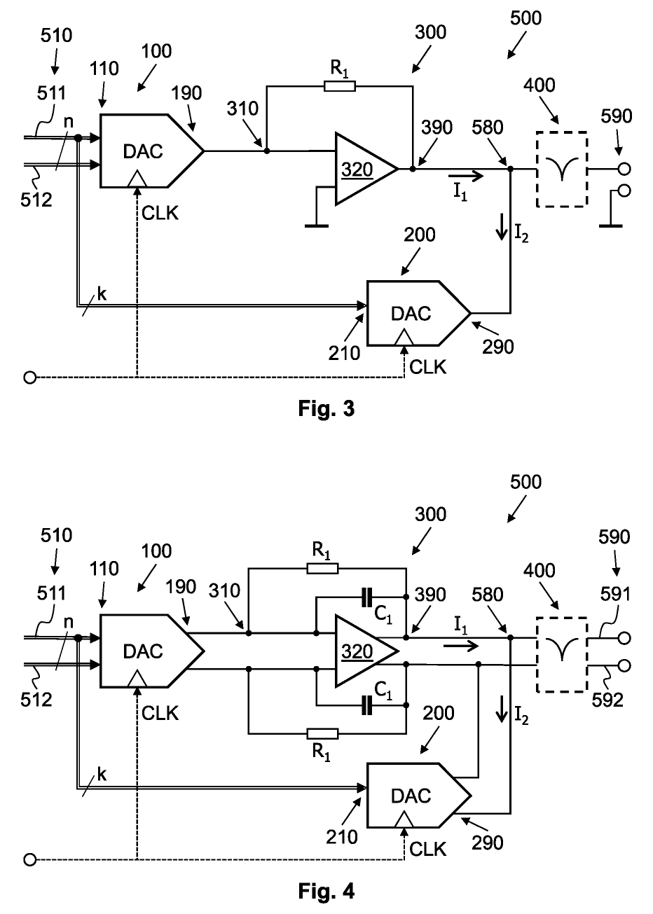

FIG. 3 schematically shows a DAC system 500 according to another embodiment. The DAC system 500 is quite similar to the DAC system 500 of FIG. 2. Same reference signs designate similar or same components. A difference to FIG. 2 is that the embodiment of FIG. 3 has single ended inputs 510 and a single ended output 590 (and 580, respectively), compared to the differential inputs and outputs of the DAC system 500 of FIG. 2.

FIG. 4 schematically shows a DAC system 500 according to a further embodiment. The DAC system 500 is quite similar to the DAC system 500 of FIG. 2. Same reference signs designate similar or same components. A difference to FIG. 2 is that the active buffer 300 is designed as an active low-pass filter. The low-pass filter 300 comprises an op-amp 320. In the feedback loops of the op-amp 320, besides a resistor R₁ (as in FIG. 2), a capacitor C₁ is arranged.

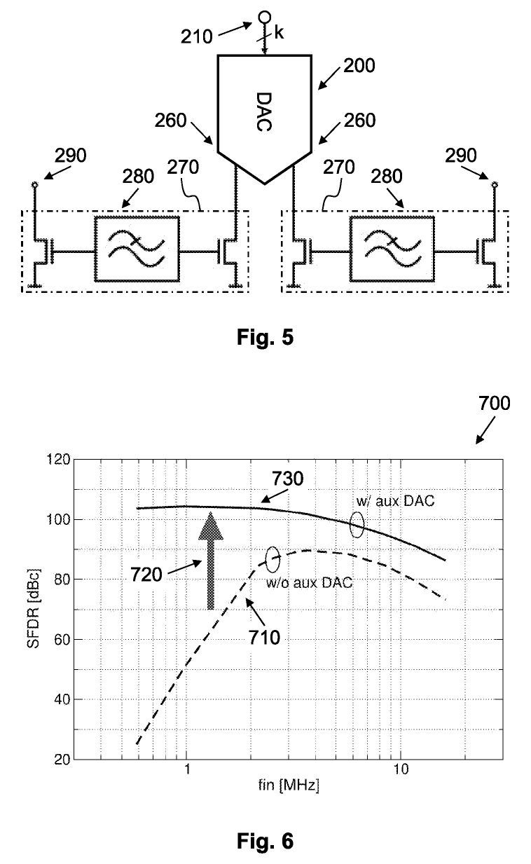

FIG. 5 schematically shows a detail of a DAC system 500 according to an embodiment. Particularly, FIG. 5 schematically shows a part of the auxiliary current-steering DAC 200 with differential outputs. Some details of the auxiliary DAC 200 are neglected in FIG. 5, e.g. an input of sampling clock CLK. The auxiliary DAC 200 gets a plurality of input lines at its input 210, e.g. k input lines from DAC system input 510. The auxiliary DAC 200 may comprise a plurality of k partial DACs, e.g. one partial DAC per bit. Their current is summed up at outputs 260. The outputs 260 are led to an output mirror circuit 270. The output mirror circuit 270 is arranged before the outputs 290 of the auxiliary current-steering DAC 200, i.e. between the outputs 260 and the outputs 290 of the auxiliary DAC 200. In the embodiment of FIG. 5, the output mirror is realized as a double mirror. The FETs of the double mirror may be realized as n-MOS FETs. The output mirror circuit 270 comprises auxiliary DAC’s low-pass filters 280, which may be, e.g., passive first order RC-filters. In an embodiment (not shown) only low-pass filters 280 may be arranged between the outputs 260 and the outputs 290 of the auxiliary DAC 200.

FIG. 6 schematically shows an example diagram 700 showing an effect of a DAC system 500 (see, e.g., FIG. 2), based on a simulation of conventional DAC system and on a simulation of a DAC system 500 according to an embodiment described above. The x-axis of FIG. 6 shows an input frequency fin of the DAC system 500, its y-axis shows a Spurious-Free Dynamic Range, SFDR, of the DAC system 500. Curve 710 shows the SFDR of a conventional DAC system over input frequency fin. Curve 710 for example shows that an SFDR over 80 dB can only be reached within a frequency range between about 2 MHz and about 10 MHz. Curve 730 shows the SFDR of the DAC system 500 according to an embodiment described above. It is clearly visible the SFDR is higher than 90 dB up to about 15 MHz, and is even higher than 100 dB within a frequency range between about 6 MHz and about 4.5 MHz. Arrow 720 emphasizes the improvement of the DAC system 500 according to an embodiment described above, compared to a conventional DAC system. Other embodiments of the DAC system 500 may be designed and/or optimized for other, for example for higher, frequency ranges.

What is claimed is:

1. A digital-to-analog converter (DAC) system comprising:
a main current-steering DAC having an input coupled to a digital system input having n input lines;
an active buffer having an input coupled to an output of the main current-steering DAC, and an output of conﬁgured to output a first current to an analog system output; and
an auxiliary current-steering DAC, having an input coupled to the digital system input, and an output conﬁgured to output a second current to the analog system output,
wherein the input of the auxiliary current-steering DAC is connected only to a real subset of the n input lines of the digital system input, the real subset of input lines having k input lines.

2. The DAC system of claim 1, wherein the real subset of the n input lines is an MSB-portion of the n input lines of the digital system input, the MSB-portion consisting of k most significant bits (MSBs) of the n input lines of the digital system input.

3. The DAC system of claim 1, wherein the real subset of the input lines consists of less than or equal to half of the n input lines of the digital system input.

4. The DAC system of claim 1, wherein the digital system input has between n=2 and n=16 input lines, and the real subset of the input lines has between k=1 and k=7 lines.

5. The DAC system of claim 1, wherein the digital system input has between n=5 and n=14 input lines, and the real subset of the input lines has between k=2 and k=6 lines.

6. The DAC system of claim 1, wherein a voltage at the input of the active buffer is configured to be compensated by the second current from the auxiliary current-steering DAC.

7. The DAC system of claim 1, further comprising:
a notch filter, arranged before the analog system output of the DAC system, the notch filter having a central frequency corresponding to a sampling frequency of the DAC system.

8. The DAC system of claim 1, wherein the active buffer is an active low-pass filter.

9. The DAC system of claim 1, wherein the second current is between 90 % and 99 % of the first current (I₁).

10. The DAC system of claim 1, wherein the real subset of the input lines of the main current-steering DAC uses a unary converter principle.

11. The DAC system of claim 1, wherein the real subset of the input lines of the auxiliary current-steering DAC uses a binary converter principle.

12. The DAC system of claim 1, wherein the auxiliary current-steering DAC further comprises a low-pass filter, the low-pass filter being arranged before the output of the auxiliary current-steering DAC.

13. The DAC system of claim 12, wherein the auxiliary current-steering DAC further comprises an output mirror, the output mirror being arranged before the output of the auxiliary current-steering DAC and comprising the low-pass filter.

14. The DAC system of claim 1, wherein the DAC system is configured to operate with a sampling frequency between 1 MHz and 1 GHz.

15. The DAC system of claim 1, wherein the digital system input comprises differential digital input, or the analog system output comprises a differential analog output.

16. The DAC system of claim 1, wherein the input of the main current-steering DAC is connected to all of the n input lines of the digital system input.

17. A system-on-chip (SoC), comprising the DAC, system of claim 1.

18. A baseband transmit circuit comprising:
a digital signal processor (DSP) having an output configured to output a digital number an output width of n bits;
a digital-to-analog converter (DAC) system comprising:
a main current-steering DAC having an input coupled to a digital system input having n input lines, wherein the digital system input is coupled to the output of the DSP,
an active buffer having an input coupled to an output of the main current-steering DAC, and an output of conﬁgured to output a first current to an analog system output. and
an auxiliary current-steering DAC, having an input coupled to the digital system input, and an output conﬁgured to output a second current to the analog system output, wherein the input of the auxiliary current-steering DAC is connected only to a real subset of the n input lines of the digital system input, the real subset of input lines having k input lines;
a low-pass filter coupled to an output of the DAC system;
a modulator conﬁgured to mix an output of the low-pass filter with an output of a local oscillator (LO);
an amplifier coupled to an output of the modulator, and conﬁgured to provide an antenna signal; and
an antenna coupled to an output of the amplifier and configured to transmit the antenna signal.

19. A method of using a digital-to-analog converter (DAC) system comprising: a main current-steering DAC having an input coupled to a digital system input having n input lines; an active buffer having an input coupled to an output of the main current-steering DAC, and an output of conﬁgured to output a first current to an analog system output; and an auxiliary current-steering DAC, having an input coupled to the digital system input, and an output conﬁgured to output a second current to the analog system output, wherein the input of the auxiliary current-steering DAC is connected only to a real subset of the n input lines of the digital system input, the real subset of input lines having k input lines, the method comprising:
converting a digital value at the digital system input to an analog value at the analog system output using the DAC system.

20. The method of claim 19, further comprising providing the analog value to at least one of a baseband transmit circuit, a WiFi system, a Bluetooth-based system, a wide-bandwidth, high-linearity baseband transmit circuit, an ultra-wideband system, a cellular system, an Ethernet system, or a cable modem system.
